(19) United States
(12) Patent Application Publication
(10) Pub. No.: US 2025/0054909 A1
(43) Pub. Date: Feb. 13, 2025

(54) SEMICONDUCTOR DEVICE

(71) Applicant: MACRONIX INTERNATIONAL CO., LTD., Hsinchu (TW)

(72) Inventors: Kai-Shiang HSU, Taichung City (TW); Jui-Chung LEE, Yunlin County (TW)

(21) Appl. No.: 18/366,116

(22) Filed: Aug. 7, 2023

(51) Int. Cl. H01L 25/065; H01L 23/00

(52) U.S. Cl. CPC H01L 25/0657; H01L 24/14; H01L 2224/14517; H01L 2225/06506; H01L 2225/0651; H01L 2225/06517; H01L 2225/06562; H01L 2225/06586

(57) ABSTRACT

A semiconductor device includes a first substrate, a first chip, a second chip, and a first substrate conductive pillar. The first chip is disposed on the first substrate and has a first lateral surface. The second chip is disposed on the first chip and includes a first protrusion protruding relative to the first lateral surface. The first substrate conductive pillar connects the first protrusion with the first substrate.

### TECHNICAL FIELD

The disclosure relates in general to a memory device.

### BACKGROUND

A semiconductor device may include a plurality of chips which are stacked or electrically connected to each other. The electrical connection interface of these chips determines the signal transmission speed and the production cost. Therefore, it is one of the goals of the industry in this technical field to propose a semiconductor device that could balance the signal transmission speed and the manufacturing cost.

### SUMMARY

Therefore, the present invention proposes a semiconductor device capable of improving the aforementioned conventional problems.

An embodiment of the present invention provides a semiconductor device. The semiconductor device includes a first substrate, a first chip, a second chip and a first substrate conductive pillar. The first chip is disposed on the first substrate and has a first lateral surface. The second chip is disposed on the first chip and includes a first protrusion protruding relative to the first lateral surface. The first substrate conductive pillar connects the first protrusion with the first substrate.

Another embodiment of the present invention provides a semiconductor device. The semiconductor device includes a substrate module and a chip module. The substrate module includes a first substrate and a plurality of substrate conductive pillars, wherein each substrate conductive pillar has an end surface, and the end surfaces of the substrate conductive pillars are different in height. The chip module has a plurality of lower surfaces, wherein the lower surfaces of the chip module are different in height. A first connection one of the substrate conductive pillars is connected to a first one of the lower surfaces of the chip module, and a second connection one of the substrate conductive pillars is connected to a second one of the lower surfaces of the chip module.

Another embodiment of the present invention provides a semiconductor device. The semiconductor device includes a first substrate, a chip module and an interposer module. The chip module is disposed on the first substrate and has a plurality of upper surfaces, wherein the surfaces of the chip module are different in height. The interposer module includes a second substrate and a plurality of interposer conductive pillars. The interposer conductive pillars are formed on the second substrate, wherein each interposer conductive pillar has an end surface, and the end surfaces of the interposer conductive pillars are different in height. A first one of the interposer conductive pillars is connected to the first substrate, and a second one of the interposer conductive pillars is connected to one of the upper surfaces of the chip module

### BRIEF DESCRIPTION OF THE DRAWINGS

FIG. 1 shows a schematic diagram of a cross-sectional view of a semiconductor device 100 according to an embodiment of the present invention;

FIG. 2 shows a schematic diagram of a cross-sectional view of a semiconductor device 200 according to another embodiment of the present invention;

FIG. 3 shows a schematic diagram of a cross-sectional view of a semiconductor device 300 according to another embodiment of the present invention;

FIG. 4 shows a schematic diagram of a cross-sectional view of a semiconductor device 400 according to another embodiment of the present invention;

FIG. 5 shows a schematic diagram of a cross-sectional view of a semiconductor device 500 according to another embodiment of the present invention;

FIG. 6 shows a schematic diagram of a cross-sectional view of a semiconductor device 600 according to another embodiment of the present invention;

FIG. 7 shows a schematic diagram of a cross-sectional view of a semiconductor device 700 according to another embodiment of the present invention;

FIG. 8A shows a schematic diagram of a perspective view of a semiconductor device 800 according to another embodiment of the present invention; and

FIG. 8B shows a schematic diagram of a top view of the semiconductor device 800 in FIG. 8A.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

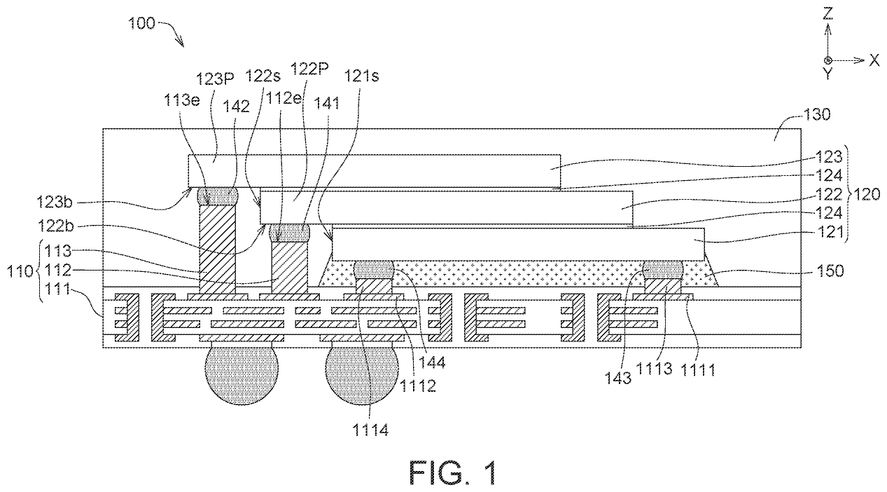

Referring to FIG. 1, FIG. 1 shows a schematic diagram of a cross-sectional view of a semiconductor device 100 according to an embodiment of the present invention. The semiconductor device 100 includes a substrate module 110, a chip module 120, a molding compound 130, at least one solder (for example, solder 141 to 144) and an underfill 150.

As shown in FIG. 1, the substrate module 110 includes a first substrate 111 and a plurality of substrate conductive pillars (for example, a first substrate conductive pillar 112 and a second substrate conductive pillar 113). The substrate conductive pillars are formed on the first substrate 111 and protrude relative to an upper surface of the first substrate 111.

As shown in FIG. 1, each substrate conductive pillar has an end surface, and the ends of the substrate conductive pillars are different in height position. For example, the first substrate conductive pillar 112 and the second substrate conductive pillar 113 are different in height position, wherein the first substrate conductive pillar 112 has an end surface 112e, the second substrate conductive pillar 113 has an end surface 113e, and the end surface 112e and the end surface 113e are different in height position (for example, in Z-axis). In addition, the “conductive pillar” herein is formed of conductive materials, for example, copper.

As shown in FIG. 1, the first substrate 111 includes a plurality of pads 1111 to 1112 and a plurality of conductive pillars 1113 to 1114, wherein the pads 1111 to 1112 are formed on a circuit layer in the first substrate 111, and the conductive pillar 1113 is formed on the pad 1111 and protrude relative to an upper surface of the first substrate 111, and the conductive pillar 1114 is formed on the pad 1112 and protrude relative to the upper surface of the first substrate 111.

As shown in FIG. 1, the chip module 120 includes a plurality of chips (for example, a first chip 121, a second chip 122 and a third chip 123) and at least one adhesive layer 124. The first chip 121 is disposed on the first substrate 111 and has a first lateral surface 121s. The second chip 122 is disposed on the first chip 121 and includes a first protrusion 122P protruding relative to the first lateral surface 121s. The first substrate conductive pillar 112 connects the first protrusion 122P with the first substrate 111. In this example, the first substrate conductive pillar 112 connects the first substrate 111 with the chip module 120 along the Z-axis without the need for TSV (through silicon via) and metal wire, and thus it can shorten the electrical conduction path (in comparison with metal wire, the present embodiment is suitable for high-frequency signal transmission) and lower manufacturing cost (in comparison with TSV).

The chip of the chip module 120 are, for example, chip with low number of I/O ports. For example, the number of I/O ports of the chip of the chip module 120 is, for example, less than 200. In semiconductor manufacturing, I/O port refers to the input and output interfaces on the chip, which ise configured for communication and data exchange with other device or system. Chips with low number of I/O ports are suitable for some specific applications which require relatively few number of I/O ports. Such design can save occupied area and reduce power consumption, and it is easier to achieve high performance and low cost. Chip with low number of I/O ports has a promising application in some specific fields, such as Internet of Things (IoT) device, embedded system, etc.

As shown in FIG. 1, the first chip 121 is, for example, a flip chip. The first chip 121 has an active surface facing the first substrate 111, and is electrically connected to the first substrate 111 downward. For example, the first chip 121 is connected to the conductive pillar 1113 of the first substrate 111 through the solder 143, and is connected to the conductive pillar 1114 of the first substrate 111 through the solder 144. The underfill 150 encapsulates the solder 143 to 144 and the conductive pillars 1113 to 1114. The solder herein is, for example, tin solder, which has conductivity.

As shown in FIG. 1, the second chip 122 has a second lateral surface 122s, and the third chip 123 is disposed on the second chip 122 and includes a second protrusion 123P protruding relative to the second lateral surface 122s. The second substrate conductive pillar 113 connects the second protrusion 123P with the first substrate 111. In this example, the second substrate conductive pillar 113 connects the first substrate 111 with the chip module 120 along the Z-axis without the need for TSV and metal wire, and thus it can shorten the electrical conduction path (in comparison with metal wire) and lower manufacturing cost (in comparison with TSV).

As shown in FIG. 1, the chip module 120 has a plurality of lower surfaces with different height positions. A first connection one of the substrate conductive pillars is connected to a first one of the lower surfaces of the chip module 120, and a second connection one of the substrate conductive pillars is connected to a second one of the lower surfaces. For example, the second chip 122 has a lower surface 122b, the third chip 123 has a lower surface 123b, the first substrate conductive pillar 112 (for example, the first connection one of the substrate conductive pillars) is connected to the lower surface 122b (for example, the first one of the lower surfaces) of the second chip 122, and the second substrate conductive pillar 113 (for example, the second connection one of the substrate conductive pillars) is connected to the lower surface 123b (for example, the second one of the lower surfaces) of the third chip 123.

As shown in FIG. 1, the first protrusion 122P of the second chip 122 has the lower surface 122b, and the first substrate conductive pillar 112 connects the lower surface 122b of the first protrusion 122P with the first substrate 111. The second protrusion 123P of the third chip 123 has the lower surface 123b, and the second substrate conductive pillar 113 connects the lower surface 123b of the second protrusion 123P with the first substrate 111. The first substrate conductive pillar 112 could be connected to the lower surface 122b of the second chip 122 through the solder 141, and the second substrate conductive pillar 113 could be connected to the lower surface 123b of the third chip 123 through the solder 142.

As shown in FIG. 1, one adhesive layer 124 could bond the first chip 121 with the second chip 122, and another adhesive layer 124 could bond the second chip 122 and the third chip 123. The adhesive layer 124 is, for example, epoxy resin or DAF (die attach film).

As shown in FIG. 1, the molding compound 130 could be formed on the first substrate 111 and encapsulates the substrate conductive pillars, the chip module 120 and the solders 141 to 142.

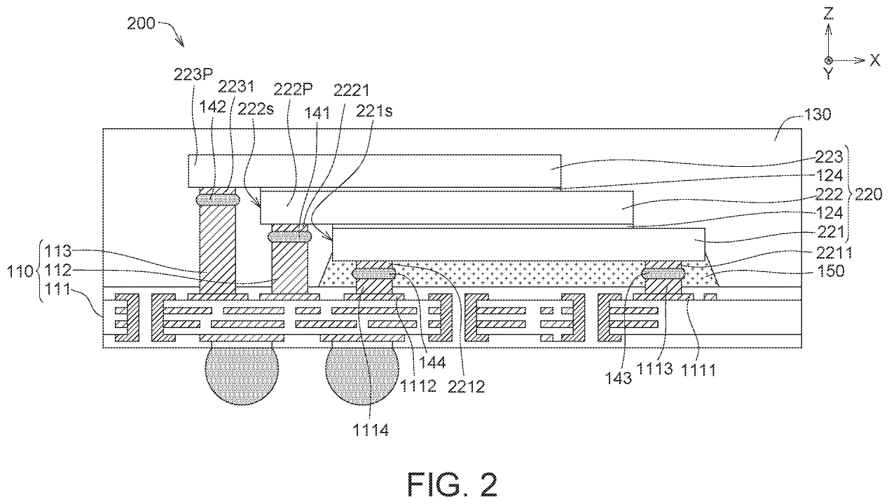

Referring to FIG. 2, FIG. 2 shows a schematic diagram of a cross-sectional view of a semiconductor device 200 according to another embodiment of the present invention. The semiconductor device 200 includes the substrate module 110, a chip module 220, the molding compound 130, at least one solder (for example, the solder 141 to 144) and the underfill 150.

The semiconductor device 200 of this embodiment includes the features similar to or the same as that of the semiconductor device 100, and one of the differences is that the chip module 220 and the chip module 120 are different in is structure.

As shown in FIG. 2, the chip module 220 includes a plurality of chips (for example, a first chip 221, a second chip 222 and a third chip 223) and at least one adhesive layer 124.

As shown in FIG. 2, the first chip 221 is disposed on the first substrate 111 and has a first lateral surface 221s. The second chip 222 is disposed on the first chip 221 and includes a first protrusion 222P protruding relative to the first lateral surface 221s. The first substrate conductive pillar 112 connects the first protrusion 222P with the first substrate 111. In this example, the first substrate conductive pillar 112 connects the first substrate 111 with the chip module 220 along the Z-axis without the need for TSV and metal wire, and thus it can shorten the electrical conduction path (in comparison with metal wire) and lower manufacturing cost (in comparison with TSV).

As shown in FIG. 2, the first chip 221 includes at least one bump, for example, bumps 2211 and 2212. The bump 2211 of the first chip 221 is connected to the conductive pillar 1113 of the first substrate 111 through the solder 143, and the bump 2212 of the first chip 221 is connected to the conductive pillar 1114 of the first substrate 111 through the solder 144.

As shown in FIG. 2, the second chip 222 has a second lateral surface 222s, and the third chip 223 is disposed on the second chip 222 and includes a second protrusion 223P protruding relative to the second lateral surface 222s. The second substrate conductive pillar 113 connects the second protrusion 223P with the first substrate 111. In this example, the second substrate conductive pillar 113 connects the first substrate 111 with the chip module 220 along the Z-axis without the need for TSV and metal wire, and thus it can shorten the electrical conduction path (in comparison with metal wire) and lower manufacturing cost (in comparison with TSV).

As shown in FIG. 2, the second chip 222 includes at least one bump 2221, and the third chip 223 includes at least one bump 2231. The first substrate conductive pillar 112 is connected to the bump 2221. For example, the first substrate conductive pillar 112 is connected to the bump 2221 through the solder 141. The second substrate conductive pillar 113 is connected to the bump 2231. For example, the second substrate conductive pillar 113 is connected to the bump 2231 through the solder 142. The “bump” herein is, for example, Under Bump Metallurgy (UMB) or copper pillar bump, and it is formed of material including copper, for example.

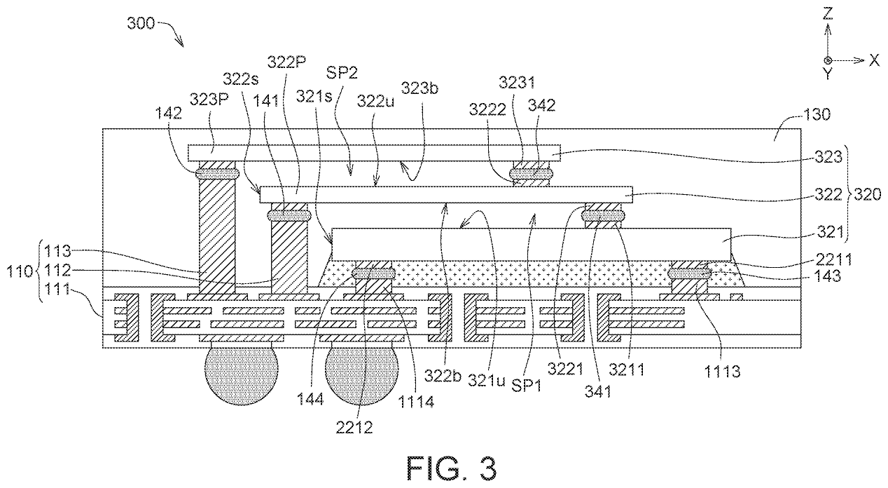

Referring to FIG. 3, FIG. 3 shows a schematic diagram of a cross-sectional view of a semiconductor device 300 according to another embodiment of the present invention. The semiconductor device 300 includes the substrate module 110, a chip module 320, the molding compound 130, at least one solder (for example, the solders 141 to 144 and solders 341 to 342), and the underfill 150.

The semiconductor device 300 of this embodiment includes the features similar to or the same as that of the semiconductor device 200, and one of the differences is that the chip module 320 and the chip module 220 are different in is structure.

As shown in FIG. 3, the chip module 320 includes a plurality of chips (for example, a first chip 321, a second chip 322 and a third chip 323). The first chip 321 is disposed on the first substrate 111 and has a first lateral surface 321s. The second chip 322 is disposed on the first chip 321 and includes a first protrusion 322P protruding relative to the first lateral surface 321s. The first substrate conductive pillar 112 connects the first protrusion 322P with the first substrate 111. In this example, the first substrate conductive pillar 112 connects the first substrate 111 with the chip module 320 along the Z-axis without the need for TSV and metal wire, and thus it can shorten the electrical conduction path (in comparison with metal wire) and lower manufacturing cost (in comparison with TSV).

As shown in FIG. 3, in the present embodiment, the first chip 321 further includes bumps 2211 to 2212. The bumps 2211 and 2212 of the first chip 321 are respectively connected to the conductive pillars 1113 and 1114 of the first substrate 111. For example, the bump 2211 of the first chip 321 is connected to the conductive pillar 1113 of the first substrate 111 through the solder 143, and the bump 2212 of the first chip 321 is connected to the conductive pillar 1114 of the first substrate 111 through the solder 144.

As shown in FIG. 3, the second chip 322 has a second lateral surface 322s, and the third chip 323 is disposed on the second chip 322 and includes a second protrusion 323P protruding relative to the second lateral surface 322s. The second substrate conductive pillar 113 connects the second protrusion 323P with the first substrate 111. In this example, the second substrate conductive pillar 113 connects the first substrate 111 with the chip module 320 along the Z-axis without the need for TSV and metal wire, and thus it can shorten the electrical conduction path (in comparison with metal wire) and lower manufacturing cost (in comparison with TSV).

As shown in FIG. 3, the first chip 321 includes at least one dummy pad 3211, and the second chip 322 includes at least one dummy bump 3221, wherein the dummy bump 3211 and the dummy pad 3221 butt. For example, the dummy bump 3211 is connected to the dummy pad 3221 through the solder 341. In this example, the dummy bump 3221, the dummy pad 3211 and the solder 341 raise the height of the second chip 322, so that there is an interval SP1 formed between the upper surface 321u of the first chip 321 and the lower surface 322b of the second chip 322, where the interval SP1 has a substantial uniform height. As a result, the second chip 322 may be substantially horizontally disposed. Due to the interval SP1 with substantial uniform height, the molding compound 130 could fill up the intervals SP1 more uniformly during the molding process. The dummy bumps and dummy pads herein refer to conductors without circuit function, which are formed of copper, for example.

As shown in FIG. 3, the second chip 322 includes at least one dummy pad 3222, and the third chip 323 includes at least one dummy bump 3231, wherein the dummy bump 3231 and the dummy pad 3222 butt. For example, the dummy bump 3231 is connected to the dummy pad 3222 through the solder 342. In this example, the dummy bump 3231, the dummy pad 3222 and the solder 342 raise the height of the third chip 323, so that there is an interval SP2 formed between the upper surface 322u of the second chip 322 and the lower surface 323b of the third chip 323, where the interval SP2 has a substantial uniform height. As a result, the second chip 322 may be substantially horizontally disposed. Due to the interval SP2 with substantial uniform height, the molding compound 130 could fill up the intervals SP2 more uniformly during the molding process.

In an embodiment, the aforementioned spaces SP1 and SP2 are at least greater than 30 microns, so that the molding compound 130 could fully fill the intervals during the molding process. In another embodiment, depending on manufacturing process, the spaces SP1 and SP2 may be equal to or less than 30 microns.

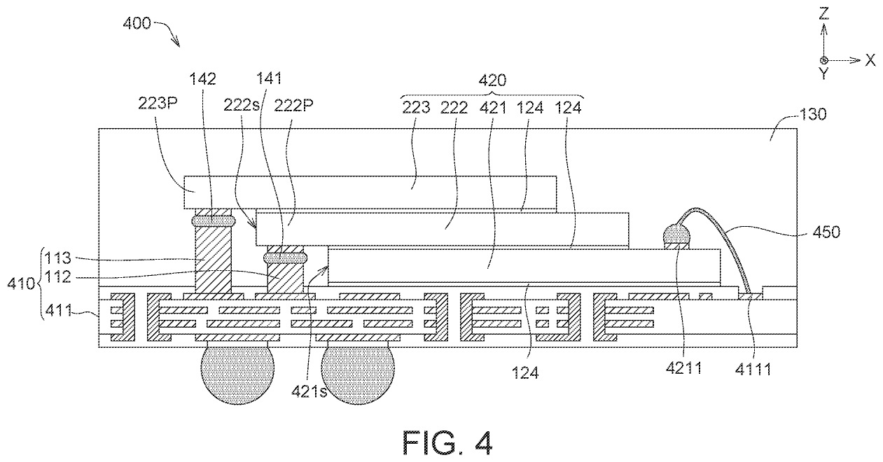

Referring to FIG. 4, FIG. 4 shows a schematic diagram of a cross-sectional view of a semiconductor device 400 according to another embodiment of the present invention. The semiconductor device 400 includes a substrate module 410, a chip module 420, the molding compound 130, at least one solder (for example, solder 141 to 142) and at least one metal wire 450.

The semiconductor device 400 of this embodiment includes the features similar to or the same as that of the semiconductor device 200, and one of the differences is that the chip module 420 and the chip module 220 are different in is structure.

As shown in FIG. 4, the substrate module 410 includes a first substrate 411, at least one first substrate conductive pillar 112 and at least one second substrate conductive pillar 113. The chip module 420 includes a plurality of chips (for example, a first chip 421, the second chip 222 and the third chip 223). The first chip 421 is disposed on the first substrate 411 and has a first lateral surface 421s. The second chip 222 is disposed on the first chip 421 and includes the first protrusion 222P protruding relative to the first lateral surface 421s. The first substrate conductive pillar 112 connects the first protrusion 222P with the first substrate 411. In this example, the first substrate conductive pillar 112 connects the first substrate 411 with the second chip 222 along the Z-axis without the need for TSV and metal wire, and thus it can shorten the electrical conduction path (in comparison with metal wire) and lower manufacturing cost (in comparison with TSV).

As shown in FIG. 4, the first chip 421 could be disposed on the first substrate 411 through the adhesive layer 124. In the present embodiment, the first chip 421 has an active surface facing upward. For example, the first chip 421 includes at least one pad 4211 exposed from the active surface of the first chip 421 to be connected with the metal wire 450.

As shown in FIG. 4, the second chip 222 has a second lateral surface 222s, and the third chip 223 is disposed on the second chip 222 and includes the second protrusion 223P protruding relative to the second lateral surface 222s. The second substrate conductive pillar 113 connects the second protrusion 223P with the first substrate 411. In this example, the second substrate conductive pillar 113 connects the first substrate 411 with the third chip 223 along the Z-axis without the need for TSV and metal wire, and thus it can shorten the electrical conduction path (in comparison with metal wire) and lower manufacturing cost (in comparison with TSV).

As shown in FIG. 4, the metal wire 450 connects the first chip 421 with the first substrate 411. For example, one end of the metal wire 450 could be bonded to the pad 4211 of the first chip 421, and the other end of the metal wire 450 could be bonded to the pad 4111 of the first substrate 411.

As shown in FIG. 4, the molding compound 130 is formed on the first substrate 411 and encapsulates the substrate conductive pillars, the chip module 420 and the metal wires 450.

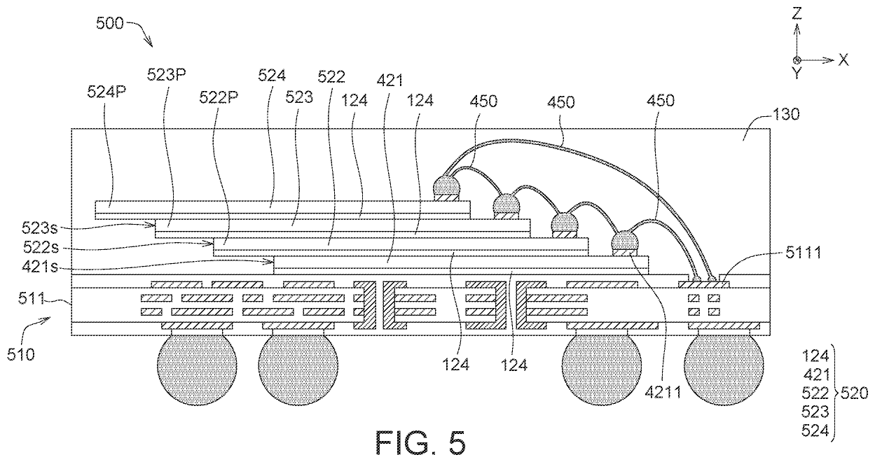

Referring to FIG. 5, FIG. 5 shows a schematic diagram of a cross-sectional view of a semiconductor device 500 according to another embodiment of the present invention. The semiconductor device 500 includes a substrate module 510, a chip module 520, the molding compound 130 and at least one metal wire 450.

The semiconductor device 500 of this embodiment includes the features similar to or the same as that of the semiconductor device 100, and one of the differences is that the chip module 520 and the chip module 120 are different in is structure.

As shown in FIG. 5, the substrate module 510 includes the first substrate 511, but may omit the first substrate conductive pillar 112 and the second substrate conductive pillar 113. The first substrate 511 includes at least one pad 5111 for connecting with at least one metal wire 450.

As shown in FIG. 5, the chip module 520 includes a plurality of chips (for example, the first chip 421, a second chip 522, a third chip 523 and a fourth chip 524). In the present embodiment, the chip module 520 could omit the substrate conductive pillars. The first chip 421 is disposed on the first substrate 511 and has the first lateral surface 421s. The second chip 122 is disposed on the first chip 421 and includes a first protrusion 522P protruding relative to the first lateral surface 421s. The second chip 522 has a second lateral surface 522s. The third chip 523 is disposed on the second chip 522 and includes a second protrusion 523P protruding relative to the second lateral surface 522s. The third chip 123 has a third lateral surface 523s. The fourth chip 524 is disposed on the third chip 523 and includes a third protrusion 524P protruding relative to the third lateral surface 523s.

As shown in FIG. 5, the first chip 421 could be disposed on the first substrate 511 through the adhesive layer 124. In the present embodiment, the first chip 421 has the active surface facing upward. For example, the first chip 421 includes at least one pad 4211 exposed from the upper surface of the first chip 421. The second chip 522, the third chip 523 and the fourth chip 524 include structures similar to that of the first chip 421. As a result, two of the first chip 421, the second chip 522, the third chip 523, the fourth chip 524 and the first substrate 511 could be connected through at least one metal wire 450.

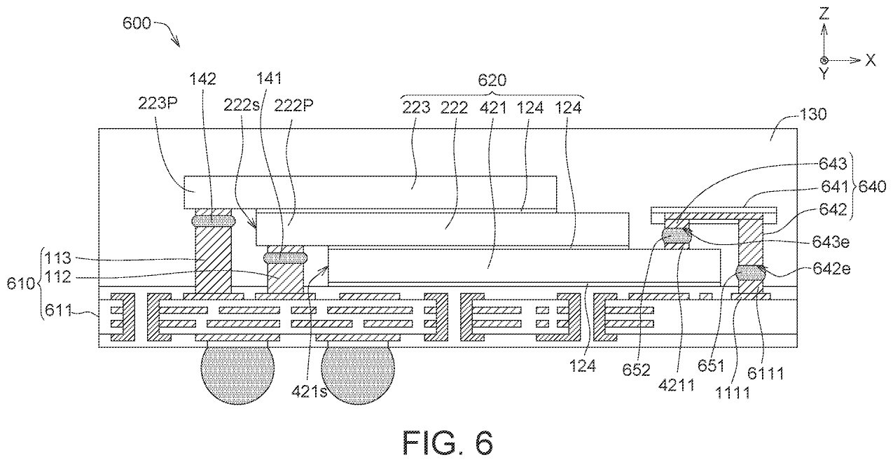

Referring to FIG. 6, FIG. 6 shows a schematic diagram of a cross-sectional view of a semiconductor device 600 according to another embodiment of the present invention. The semiconductor device 600 includes a substrate module 610, a chip module 620, the molding compound 130, an interposer module 640 and at least one solder (for example, the solders 141 to 142 and solders 651 to 652).

The semiconductor device 600 of this embodiment includes the features similar to or the same as that of the semiconductor device 200, and one of the differences is that the substrate module 610 and the substrate module 210 are different in is structure, and the semiconductor device 600 further includes the interposer module 640.

As shown in FIG. 6, the substrate module 610 includes a first substrate 611, at least one first substrate conductive pillar 112 and at least one second substrate conductive pillar 113. The first substrate 611 includes at least one pad 1111 and at least one bump 6111.

As shown in FIG. 6, the interposer module 640 includes a second substrate 641 and a plurality of interposer conductive pillars (for example, a first interposer conductive pillar 642 and a second interposer conductive pillar 643). The interposer conductive pillars are formed on the second substrate 641, and each interposer conductive pillar has an end surface. The end surfaces of the interpose layer conductive pillars are different in the height position. For example, the first interposer conductive pillar 642 has an end surface 642e, the second interposer conductive pillar 643 has an end surface 643e, and the end surface 642e and the end surface 643e are different in height position (for example, in Z-axis). In addition, the end surface 642e of the first interposer conductive pillar 642 is connected to the bump 6111 through the solder 651, and the end surface 643e of the second interposer conductive pillar 643 is connected to the pad 4211 through the solder 652.

As shown in FIG. 6, the chip module 620 includes a plurality of chips (for example, the first chip 421, the second chip 222 and the third chip 223). The first chip 421 is disposed on the first substrate 611 and has the first lateral surface 421s. The second chip 222 is disposed on the first chip 421 and includes the first protrusion 222P protruding relative to the first lateral surface 421s. The second chip 222 has the second lateral surface 222s. The third chip 223 is disposed on the second chip 222 and includes the second protrusion 223P protruding relative to the second lateral surface 222s.

As shown in FIG. 6, due to the second chip 222 moving leftward relative to the first chip 421 to expose the upper surface of the first chip 421, the interposer module 640 could be connected to the exposed first chip 421.

As shown in FIG. 6, one of the interposer conductive pillars is connected to one of the first substrate 611, the first chip 421 and the second chip 222, and another of the interposer conductive pillars is connected to another of the first substrate 611, the first chip 421 and the second chip 222. For example, the first interposer conductive pillar 642 is connected to the first substrate 611 through the solder 651, and the second interposer conductive pillar 643 is connected to the first chip 421 through the solder 652.

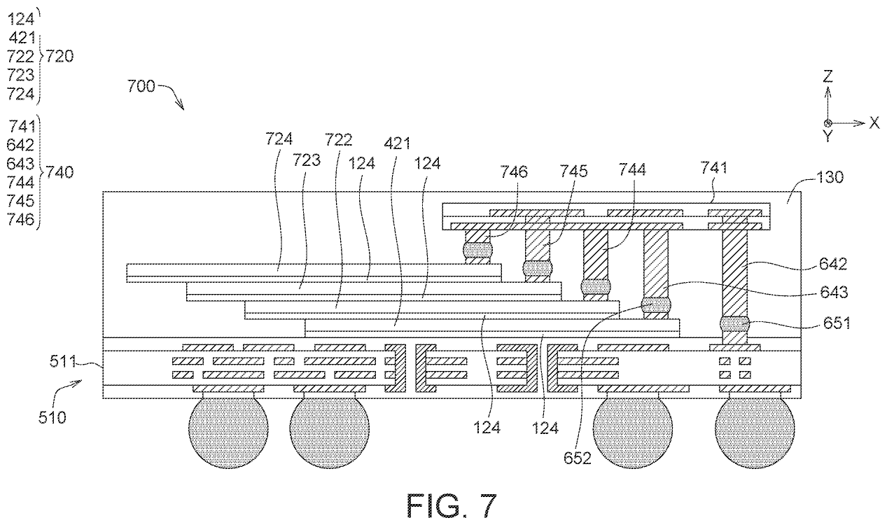

Referring to FIG. 7, FIG. 7 shows a schematic diagram of a cross-sectional view of a semiconductor device 700 according to another embodiment of the present invention. The semiconductor device 700 includes the substrate module 510, a chip module 720, the molding compound 130, an interposer module 740 and at least one solder (for example, solder 651 to 652).

The semiconductor device 700 of this embodiment includes the features similar to or the same as that of the semiconductor device 600, and one of the differences is that the interposer module 740 of the semiconductor device 700 and the interposer module 640 are different in structure. Compared with the interposer module 640, the interposer module 740 includes more interposer conductive pillars.

As shown in FIG. 7, the chip module 720 includes a plurality of chips (for example, the first chip 421, a second chip 722, a third chip 723 and a fourth chip 724). The interposer module 740 includes a second substrate 741, interposer conductive pillars 642, 643, 744, 745 and 746. The interposer conductive pillar 642, the interposer conductive pillar 643, the interposer conductive pillar 744, the interposer conductive pillar 745, and the interposer conductive pillar 746 are respectively connected to the first substrate 511, the first chip 421, the second chip 722, the third chip 723 and the fourth chip 724. The connection method between the interposer conductive pillar 643 and the first chip 421 has been described above. The connection method between the interposer conductive pillar 744 and the second chip 722, the connection method between the interposer conductive pillar 745 and the third chip 723, and the connection method between the interposer conductive pillar 746 and the fourth chip 724 are similar to or the same as the connection method between the interposer conductive pillar 643 and the first chip 421, and they will not be repeated here.

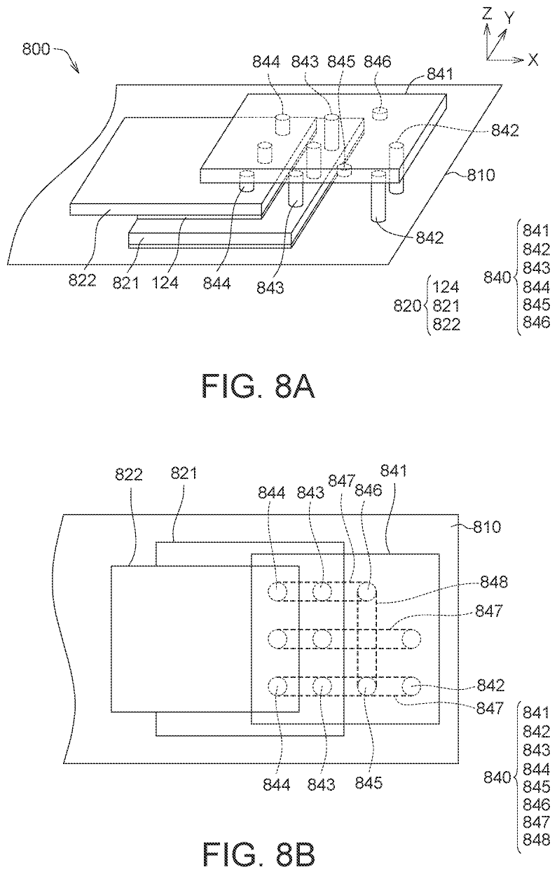

Referring to FIGS. 8A to 8B, FIG. 8A shows a schematic diagram of a perspective view of a semiconductor device 800 according to another embodiment of the present invention, and FIG. 8B shows a schematic diagram of a top view of the semiconductor device 800 in FIG. 8A. The semiconductor device 800 includes a substrate module 810, a chip module 820, the molding compound 130 and an interposer module 840.

The interposer module 840 includes a second substrate 841 and at least one interposer conductive pillar (for example, at least one first interposer conductive pillar 842, at least one second interposer conductive pillar 843, and at least one third interposer conductive pillar 844), at least one conductive via (for example, conductive vias 845 and 846) and at least one circuit layers (for example, at least one first circuit layer 847 and at least one second circuit layer 848). One of the first interposer conductive pillars 842, one of the second interposer conductive pillars 843 and/or one of the third interposer conductive pillars 844 is connected with one of the first circuit layers 847, extends from the first circuit layer 847 toward the substrate module 810, and is connected to the substrate module 810. Another of the first interposer conductive pillars 842, another of the second interposer conductive pillars 843 and/or another of the third interposer conductive pillars 844 is connected with another of the first circuit layers 847, extends from the first circuit layer 847 toward the substrate module 810, and is connected to the substrate module 810. The conductive vias 845 and 846 are formed inside the interposer module 840, and connect the first circuit layer 847 with the second circuit layer 848, wherein the second circuit layer 848 and the first circuit layer 847 are respectively located in different layers with height differences. In an embodiment, the first circuit layer 847 is closer to the substrate module 810 than the second circuit layer 848 in the Z-axis. As described above, through the conductive vias, the first circuit layers and the second circuit layer, two of the first interposer conductive pillar, the second interposer conductive pillar and the third interposer conductive pillar could be electrically connected, two of the first interposer conductive pillars could be electrically connected, two of the second interposer conductive pillars could be electrically connected, and/or two of the third interposer conductive pillars could be electrically connected.

To sum up, the embodiment of the present invention provides a semiconductor device. In an embodiment, the semiconductor device includes a substrate module and a chip module, wherein the substrate module includes a first substrate and a plurality of substrate conductive pillars, wherein the substrate conductive pillars protrude relative to a surface of the first substrate. A plurality of the substrate conductive pillars has height differences, so as to connect a plurality of chips with height differences in the chip module. As a result, the substrate conductive pillar connects the first substrate with the chip module along a thickness of the semiconductor device without the need for TSV and metal wire, and thus it can shorten the electrical conduction path and lower manufacturing cost. In another embodiment, the semiconductor device includes a substrate module, a chip module, and an interposer module, wherein the interposer module includes a second substrate and a plurality of interposer conductive pillars, and the interposer conductive pillars protrude relative to a surface of the second substrate. A plurality of interposer conductive pillars has height differences, so as to connect a plurality of chips with height differences in the chip module and/or the first substrate of the substrate module.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor device, comprising:
a first substrate;
a first chip disposed on the first substrate and having a first lateral surface; and
a second chip disposed on the first chip and comprising a first protrusion protruding with respect to the first lateral surface;
a first substrate conductive pillar connecting the first protrusion with the first substrate.

2. The semiconductor device according to claim 1, wherein the second chip has a second lateral surface and the semiconductor device comprises:
a third chip disposed on the second chip and comprising a second protrusion protruding with respect to the second lateral surface; and
a second substrate conductive pillar connecting the second protrusion with the first substrate.

3. The semiconductor device according to claim 2, wherein the first substrate conductive pillar and the second substrate conductive pillar are different in height.

4. The semiconductor device according to claim 1, wherein the first chip comprises a dummy pad, the second chip comprises a dummy bump, and the dummy bump is connected to the dummy pad.

5. The semiconductor device according to claim 1, wherein the second chip has a lower surface, the first has an upper surface, there is an interval between the lower surface and the upper surface, and the semiconductor device further comprises:
a molding compound filling the interval.

6. The semiconductor device according to claim 1, further comprising:
an interposer module, comprising:
a second substrate; and
a plurality of interposer conductive pillars formed on the second substrate, wherein each interposer conductive pillar has an end surface, and the end surfaces of the interposer conductive pillars are different in height;
wherein one of the interposer conductive pillars is connected to one of the first substrate, the first chip and the second chip, and another of the interposer conductive pillars is connected to another of the first substrate, the first chip and the second chip.

7. The semiconductor device according to claim 1, further comprising:
a metal wire connecting the first substrate with the first chip.

8. The semiconductor device according to claim 1, further comprising:
an interposer module, comprising:
a plurality of first circuit layers;
a second circuit layer, wherein the second circuit layer and each the first circuit layer are respectively located in different heights;
a plurality of conductive vias connecting the first circuit layer with the second circuit layer; and
a plurality of interposer conductive pillars, wherein one of the interposer conductive pillars is connected with one of the first circuit layers, and another of the interposer conductive pillars is connected with another of the first circuit layers.

9. A semiconductor device, comprising:
a substrate module, comprising:
a first substrate;
a plurality of substrate conductive pillars formed on the first substrate,
wherein each substrate conductive pillar has an end surface, and the end surfaces of the substrate conductive pillars are different in height;
a chip module having a plurality of lower surfaces, wherein the lower surfaces of the chip module are different in height;
wherein a first connection one of the substrate conductive pillars is connected to a first one of the lower surfaces of the chip module, and a second connection one of the substrate conductive pillars is connected to a second one of the lower surfaces of the chip module.

10. The semiconductor device according to claim 9, wherein the chip module comprising:
a first chip having a first lateral surface;
a second chip comprising a first protrusion protruding with respect to the first lateral surface, wherein the first protrusion has the first one of the lower surfaces;
wherein the first connection one of the substrate conductive pillars connects the first protrusion with the first substrate.

11. The semiconductor device according to claim 10, wherein the second chip has a second lateral surface and further comprises:
a third chip disposed on the second chip and comprising a second protrusion protruding with respect to the second lateral surface, wherein the second protrusion has the second one of the lower surfaces;
wherein the second one of the substrate conductive pillars connects the second protrusion with the first substrate.

12. The memory device according to claim 10, wherein the first chip comprises a dummy pad, the second chip comprises a dummy bump, and the dummy bump is connected to the dummy pad.

13. The semiconductor device according to claim 10, wherein the second chip has the first one of the lower surfaces, the first has an upper surface, there is an interval between the lower surface and the first one of the lower surfaces of the second chip, and the semiconductor device further comprises:
a molding compound filling the interval.

14. The semiconductor device according to claim 13, further comprising:
an interposer module, comprising:
a second substrate; and
a plurality of interposer conductive pillars formed on the second substrate, wherein each interposer conductive pillar has an end surface, and the end surfaces of the interposer conductive pillars are different in height;
wherein one of the interposer conductive pillars is connected to one of the first substrate, the first chip and the second chip, and another of the interposer conductive pillars is connected to another of the first substrate, the first chip and the second chip.

15. The semiconductor device according to claim 9, further comprising:
a metal wire connecting the first substrate with the first chip.

16. A semiconductor device, comprising:
a first substrate;
a chip module disposed on the first substrate and having a plurality of upper surfaces, wherein the surfaces of the chip module are different in height;
an interposer module, comprising:
a second substrate; and
a plurality of interposer conductive pillars formed on the second substrate, wherein each interposer conductive pillar has an end surface, and the end surfaces of the interposer conductive pillars are different in height;
wherein a first one of the interposer conductive pillars is connected to the first substrate, and a second one of the interposer conductive pillars is connected to one of the upper surfaces of the chip module.

17. The semiconductor device according to claim 16, wherein the chip module comprising:
a first chip comprising a protrusion;
a second chip having a lateral surface;
wherein the protrusion of the first chip protrudes with respect to the lateral surface of the second chip, and the second one of the interposer conductive pillars is connected to the protrusion.

18. The semiconductor device according to claim 17, further comprising:
a first substrate conductive pillar connecting the first chip with the first substrate.

19. The semiconductor device according to claim 16, further comprising:
a molding compound formed on the first substrate and encapsulating the chip module and the interposer module.

20. The semiconductor device according to claim 16, wherein the interposer module further comprises:
a plurality of first circuit layers;
a second circuit layer, wherein the second circuit layer and each the first circuit layer are respectively located in different heights;
a plurality of conductive vias connecting the first circuit layer with the second circuit layer;
wherein one of the interposer conductive pillars is connected with one of the first circuit layers, and another of the interposer conductive pillars is connected with another of the first circuit layers.
